(19) United States
(12) Patent Application Publication
(10) Pub. No.: US 2005/0248011 A1
(43) Pub. Date: Nov. 10, 2005

(54) Flip chip semiconductor package for testing bump and method of fabricating the same

(75) Inventors: Jin-Kook Jung, Seongnam-si (KR); Yong-Tae Bae, Siheung-si (KR); Young-Dae Kim, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/121,885

(22) Filed: May 4, 2005

(30) Foreign Application Priority Data
May 4, 2004 (KR) 2004-31357

(51) Int. Cl. H01L 23/02

(52) U.S. Cl. 257/678

(57) ABSTRACT

A semiconductor package comprises a plurality of pads disposed along a surface edge of a semiconductor chip, a plurality of mounting bumps formed on a surface of the semiconductor chip and disposed away from the plurality of pads at a predetermined distance, a plurality of redistribution connecting wires for electrically connecting the plurality of pads to the plurality of mounting bumps, and a plurality of test bumps disposed on the plurality of pads.

### BACKGROUND

This application claims priority to Korean Patent Application No. 2004-31357, filed on May 4, 2004, in the Korean Intellectual Property Office, the disclosure of which is incorporated herein in its entirety by reference.

1. Technical Field

The present disclosure relates to a semiconductor package and a method of fabricating the same, and more particularly, to a flip chip semiconductor package for testing a bump and a method of fabricating the same.

2. Discussion of Related Art

The number of input/output terminals of a semiconductor device becomes increased as integration of the semiconductor device increases. A surface-mount type package becomes used more often than a pin-insertion type package because a number of outer leads that can be formed on a circuit board are limited in the pin-insertion type package. Package methods such as a ball grid array (BGA) package and a chip scale package are proposed to dispose a semiconductor chip in a smaller space. The semiconductor chip is mounted on a package. The semiconductor chip and the package are connected using electric connecting methods such as a wire bonding, a tape automated bonding, and a flip chip bonding.

The size of a semiconductor package using the flip chip bonding can be smaller than the size of a semiconductor package using the wire bonding. The flip chip package has a high speed electric characteristic and the input/output terminals can be formed in any position of the semiconductor chip. The size of the flip chip package can be reduced by a redistribution of bumps.

FIGS. 1 through 3 show a conventional flip chip semiconductor package and a method of fabricating the same. Referring to FIG. 1, a plurality of upper pads 112 are formed on an edge of an insulating layer 101. The upper pads 112 are electrically connected to a plurality of lower pads (not shown) by via contact holes (not shown). Referring to FIG. 2, a plurality of redistribution connecting wires 120 are formed and connected to the plurality of upper pads 112. The redistribution connecting wires 120 can be formed of a conductive layer. The redistribution connecting wires extend from the upper pads 112 toward a center of the package. Referring to FIG. 3, a passivation layer 103 is formed on the package. The passivation layer 103 has openings for exposing the redistribution connecting wires 120. Bumps 142 can be formed on the exposed portions of the redistribution connecting wires 120 through a conventional process.

An electrical die sorting (EDS) test is performed to test electric characteristics for the flip chip package. The EDS test includes a method using a vertical probe card and a method using a conventional probe card.

Referring to FIG. 4, an EDS test using a vertical probe card 300 is shown. The vertical probe card 300 includes a body 310 and a plurality of probes 320 disposed on a bottom surface of the body 310. The probes 320 are arranged corresponding to the bumps 142. Then, the vertical probe card 300 descends so that the probes 320 contact the corresponding bumps 142 of the flip chip semiconductor package. Then, a signal is applied to perform the EDS test.

An EDS test using the conventional probe card needs to be performed on the upper pads 112 shown in FIG. 1 because probes of the conventional probe card cannot be arranged corresponding to the bumps 142.

When the vertical probe card 300 is used for the EDS test the manufacturing cost of the flip chip semiconductor package can be increased because the vertical probe card 300 is expensive. When the conventional probe card is used for the EDS test, the flip chip package can be contaminated because the flip chip package needs to be transferred to a test line during a package fabrication process.

### SUMMARY OF THE INVENTION

In one exemplary embodiment of the present invention, a semiconductor package comprises a plurality of pads disposed along a surface edge of a semiconductor chip, a plurality of mounting bumps formed on a surface of the semiconductor chip and disposed away from the plurality of pads at a predetermined distance, a plurality of redistribution connecting wires for electrically connecting the plurality of pads to the plurality of mounting bumps, and a plurality of test bumps disposed on the plurality of pads.

In another exemplary embodiment of the present invention, a semiconductor package comprises a semiconductor chip, a plurality of pads disposed along a surface edge of the semiconductor chip, a plurality of mounting bumps formed on a surface of the semiconductor chip and disposed away from the plurality of pads at a predetermined distance, a plurality of redistribution connecting wires for electrically connecting the plurality of pads to the plurality of mounting bumps, and a plurality of test bumps disposed between the plurality of pads and the plurality of mounting bumps.

In still another exemplary embodiment of the present invention, a method for fabricating a semiconductor package comprises forming a first insulating layer on a semiconductor chip, the first insulating layer having openings for exposing a portion of a plurality of pads of the semiconductor chip, forming a plurality of redistribution connecting wires on the first insulating layer, wherein the plurality of redistribution connecting wires are electrically connected to the plurality of pads, forming a second insulating layer having openings for exposing a first region and a second region of the plurality of redistribution connecting wires, and forming a plurality of mounting bumps and a plurality of test bumps on the first region and the second region of the plurality of redistribution connecting wires, respectively.

The above and other exemplary embodiments will become more apparent by describing in detail exemplary embodiments thereof with reference to the accompanying drawings.

### BRIEF DESCRIPTION OF THE DRAWINGS

FIGS. 1 through 3 are plan views illustrating a fabrication process of a conventional flip chip semiconductor package.

FIG. 4 is a sectional view illustrating an exemplary embodiment of an EDS test with respect to a conventional flip chip semiconductor package.

FIGS. 5 through 8 are plan views illustrating a flip chip semiconductor package fabricating method according to an exemplary embodiment of the present invention.

FIGS. 9 and 10 are plan views illustrating a flip chip semiconductor package fabricating method according to another exemplary embodiment of the present invention.

FIGS. 11 through 14 are sectional views taken along lines A-A′ of FIGS. 5 through 8, respectively.

FIGS. 15 and 16 are sectional views taken along lines A-A′ of FIGS. 9 and 10.

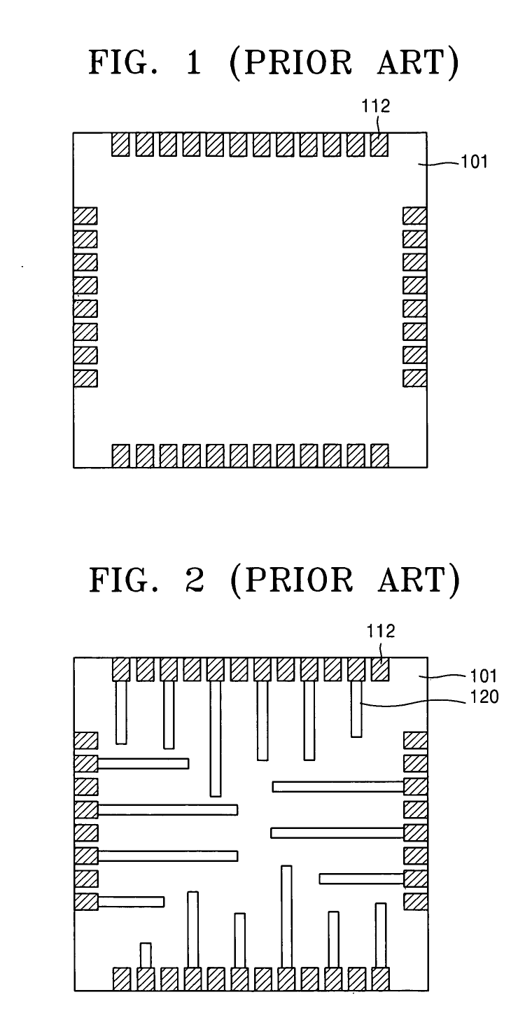

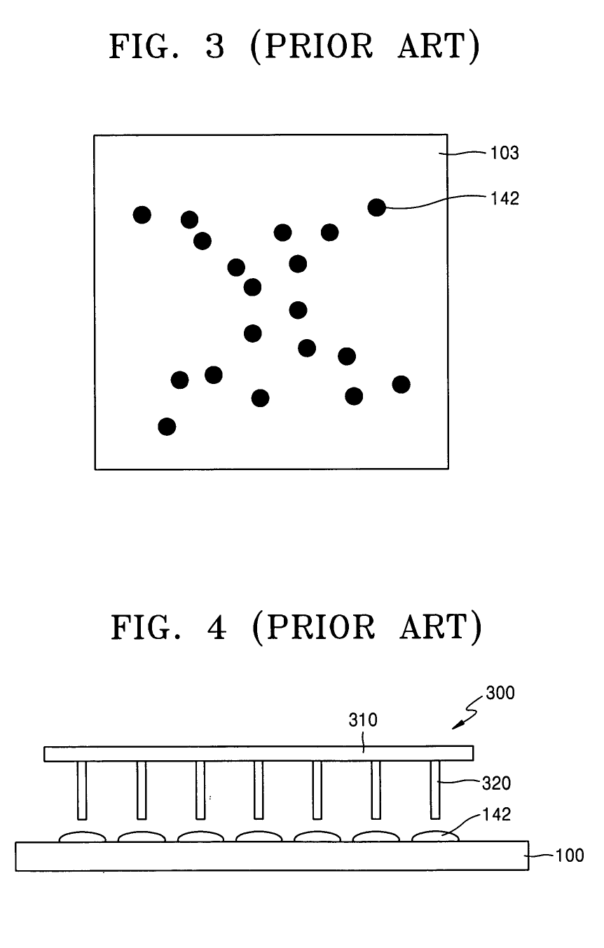

### DETAILED DESCRIPTION OF EXEMPLARY EMBODIMENTS

Exemplary embodiments of the present invention will now be described more fully with reference to the accompanying drawings. The invention may, however, be embodied in many different forms and should not be construed as being limited to the exemplary embodiments set forth herein. Rather, these exemplary embodiments are provided so that this disclosure will be thorough and complete, and will fully convey the concept of the invention to those skilled in the art. In the drawings, the thicknesses of layers and regions are exaggerated for clarity.

FIGS. 8 and 14 show a flip chip semiconductor package according to an exemplary embodiment of the present invention. The flip chip semiconductor package includes a semiconductor chip 200, an insulating layer 201, lower pads 211, a contact layer 202, upper pads 212, mounting bumps 241, redistribution connecting wires 220, and test bumps 242. The insulating layer 201 is formed on a surface of the semiconductor chip 200, on which lower pads 211 are formed. The insulating layer 201 formed on the surface of the semiconductor chip 200 covers the lower pads 211. The upper pads 212 are formed on the insulating layer 201. The upper pads 212 are electrically connected to the lower pads 211 by via contact holes 202 penetrating the insulating layer 201. The redistribution connecting wires 220 are disposed on a portion of the insulating layer 201. The redistribution connecting wires 220 can be formed of a conductive layer and extend from the upper pads 212 toward a center of the flip chip semiconductor package.

A passivation layer 203 covers the upper pads 212, the redistribution connecting wires 220 and the insulating layer 201. The passivation layer 203 has first openings 231 for exposing a portion of the upper pads 212 and second openings 232 for exposing a portion of the redistribution connecting wires 220. Generally, the second openings 232 are formed corresponding to first ends of the redistribution connecting wires 220, which are opposite from the upper pads 212. The mounting bumps 242 are disposed on a portion of the redistribution connecting wires 220, which are exposed by the second openings 232. The test bumps 241 are designed to contact probes of the conventional probe card during the EDS test. The mounting bumps 242 are designed to be flip-chip-bonded when mounting the flip chip semiconductor package on a printed circuit board or a substrate. The test bumps 241 and the mounting bumps 242 can be formed of a same material through a same fabrication process.

According to exemplary embodiments of the present invention, the flip chip semiconductor package can be fabricated without a separate test performed outside of a fabrication line. Contamination of the flip chip semiconductor package can be prevented because the flip chip package does not need to be transferred to a test line while fabricating the flip chip package.

According to exemplary embodiments of the present invention, an EDS test for a finalized flip chip package can be performed using the conventional probe card. The probes of the conventional probe card contact the test bumps 241 of the flip chip semiconductor package. Since the test bumps 241 are disposed above the upper pads 212, the probes of the conventional probe card can contact the test bumps 241 which are positioned on the upper pads 212. After the probes contact the test bumps 241, a signal based on an EDS test program is applied to detect defects.

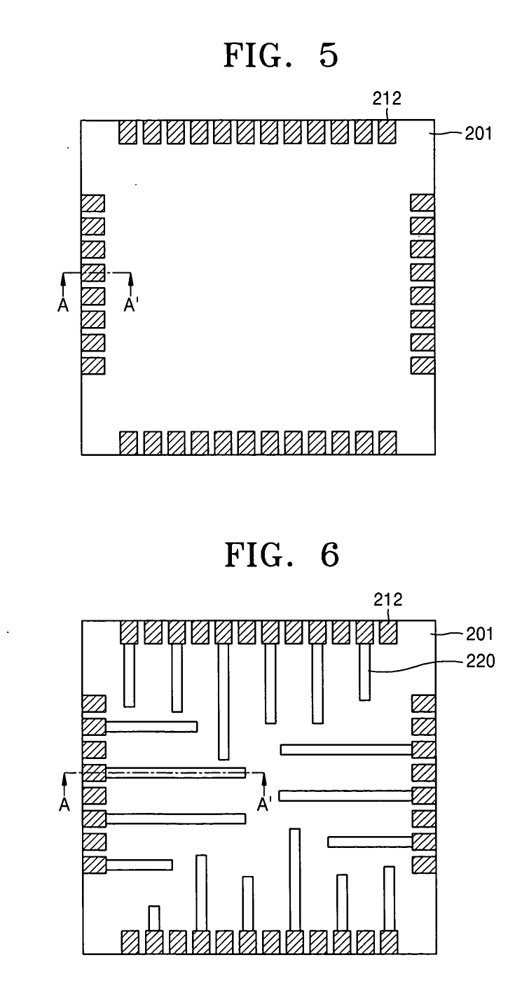

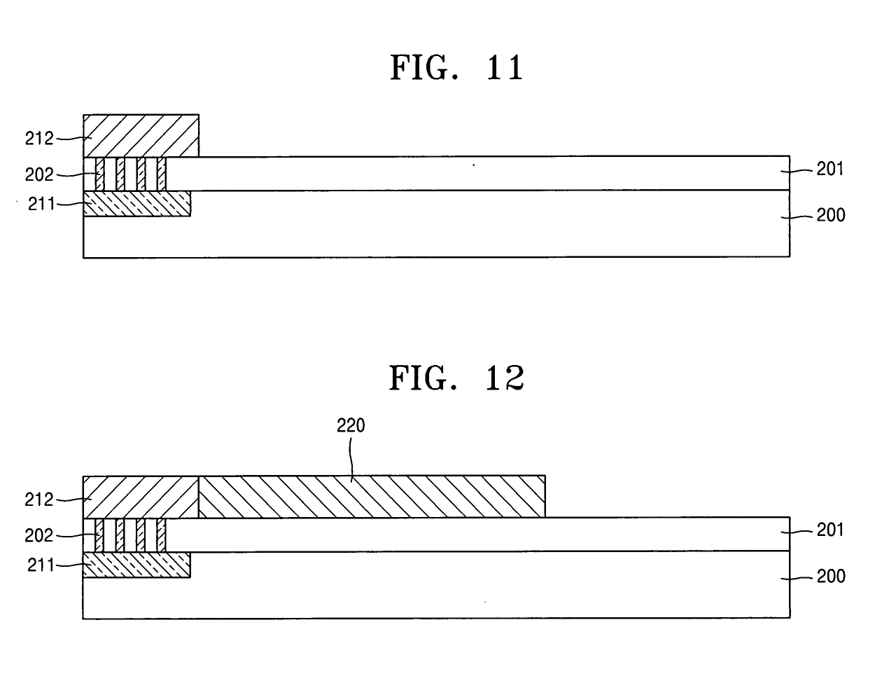

A flip chip semiconductor package fabricating process is described with reference to FIGS. 5 through 8 and 11 through 14 according to an exemplary embodiment of the present invention. Referring to FIGS. 5 and 11, the insulating layer 201 is formed on the semiconductor chip 200 and the lower pads 211. The lower pads 211 are disposed at edges of the semiconductor chip 200. The via contact holes 202 are formed penetrating the insulating layer 201. The upper pads 212 and the lower pads 211 contact each other by the via contact holes 202.

Referring to FIGS. 6 and 12, the redistribution connecting wires 220 are formed on the insulating layer 201. The redistribution connecting wires 220 can be formed of a conductive layer through a conventional metallization process. The redistribution connecting wires 220 extend from the upper pads 212 toward the center of the flip chip semiconductor package. In exemplary embodiments of the present invention, lengths of the redistribution connecting wires 220 can be different from each other based on positions of the second openings 232.

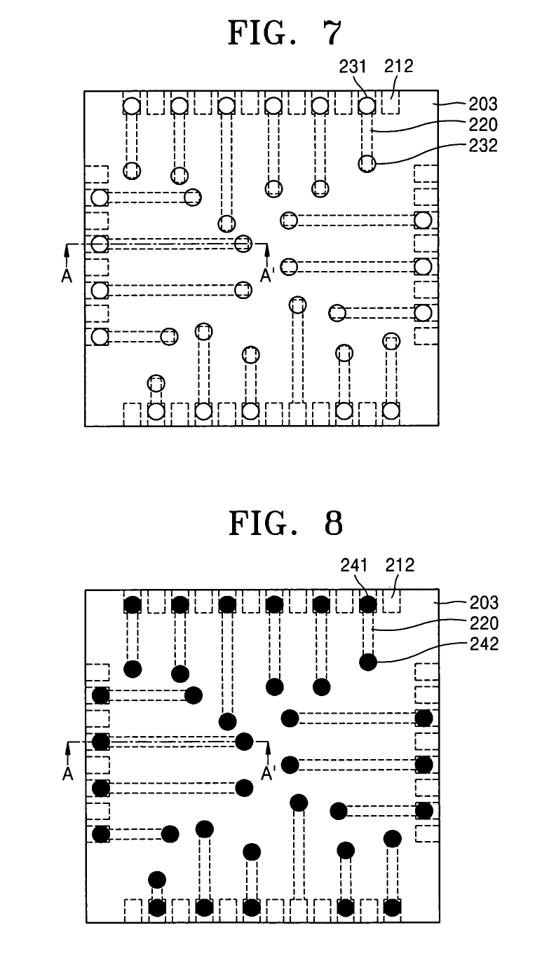

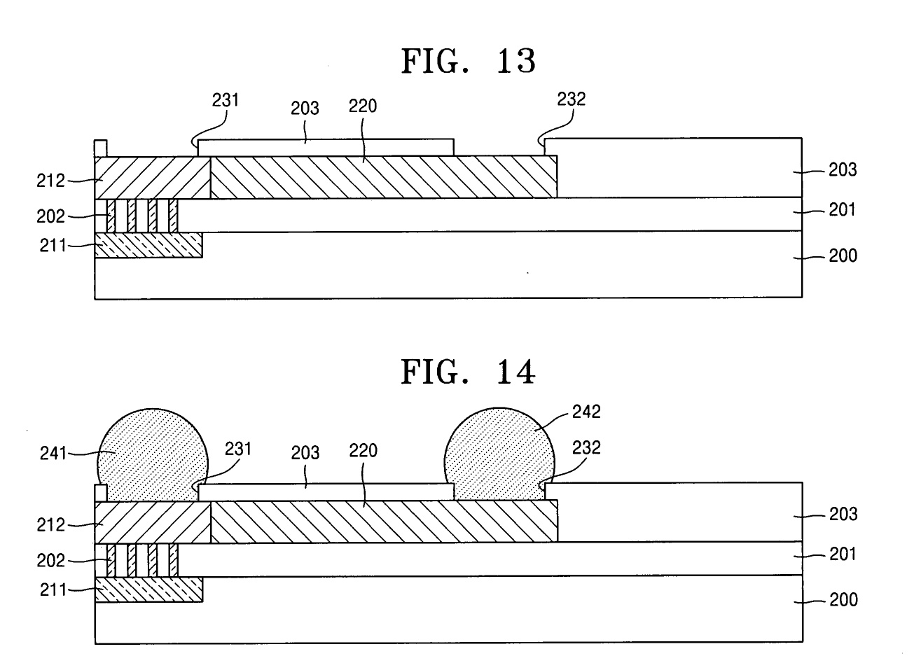

Referring to FIGS. 7 and 13, the passivation layer 203 covers the upper pads 212, the redistribution connecting wires 220 and the insulating layer 201. The first openings 231 and the second openings 232 for exposing a portion of each upper pad 212 and a portion of each redistribution connecting wire 220 are formed by removing a portion of the passivation layer 203. The first openings 231 are formed on the upper pads 212, and the second openings 232 are formed on the redistribution connecting wires 220.

Referring to FIGS. 8 and 14, the test bumps 241 and the mounting bumps 242 are formed using a conventional bump forming method such as, for example, an electrolytic plating process, a screen printing process, a ball placement process. The test bumps 241 are disposed on the portions of the upper pads 212 exposed by the first openings 231. The mounting bumps 242 are disposed on portions of the redistribution connecting wires 220 exposed by the second openings 232. The test bumps 241 and the mounting bumps 242 can be formed of gold or solder.

Referring to FIGS. 10 and 16, test bumps 341 are positioned on exposed portions of the redistribution connecting wires 220 according to another exemplary embodiment of the present invention.

The passivation layer 303 covers the upper pads 212, the redistribution connecting wires 220 and the insulating layer 201. The passivation layer 303 includes first openings 331 and second openings 332 for exposing portions of each redistribution connecting wire 220. The first openings 331 are formed on the passivation layer close to the upper pads 212. The second openings 332 are formed on the passivation layer 303 close to the center of the flip chip semiconductor package.

The test bumps 341 are disposed on portions of the redistribution connecting wires 220 exposed by the first openings 331. The mounting bumps 342 are disposed on portions of the redistribution connecting wires 220 exposed by the second openings 332. A distance between the mounting bumps 342 and the upper pads 212 can be changed. However, a distance (shown as “d” on FIG. 10) between the test bumps 341 and the upper pads 212 is substantially the same. Thus, the EDS test using the conventional probe card can be performed on the test bumps 341. The flip chip semiconductor package according to the exemplary embodiment of the present invention can be used when a size of one of the test bumps 341 is greater than a size of one of the upper pads 212.

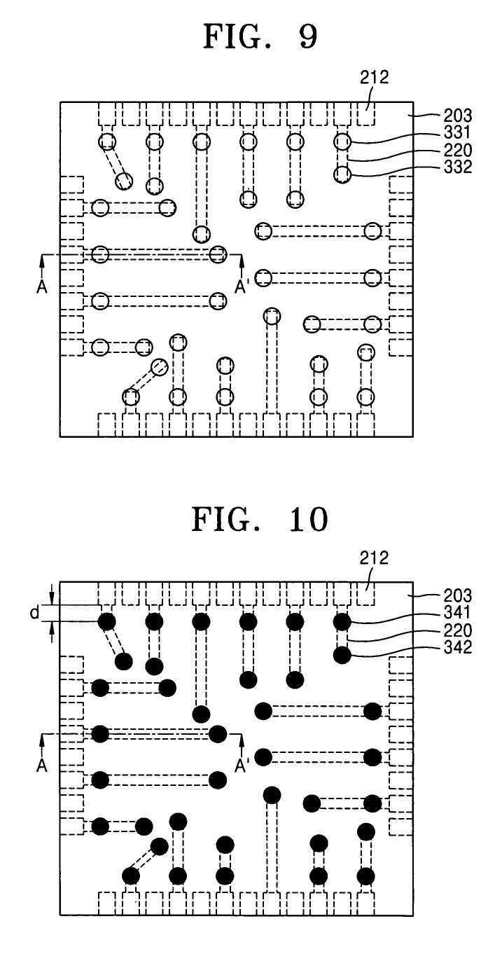

Referring to FIGS. 9, 10, 15, and 16, the insulating layer 201 is formed on the semiconductor chip 200, and the upper pads 212 are formed on the insulating layer 201. The redistribution connecting wires 220 are formed on the insulating layer 201.

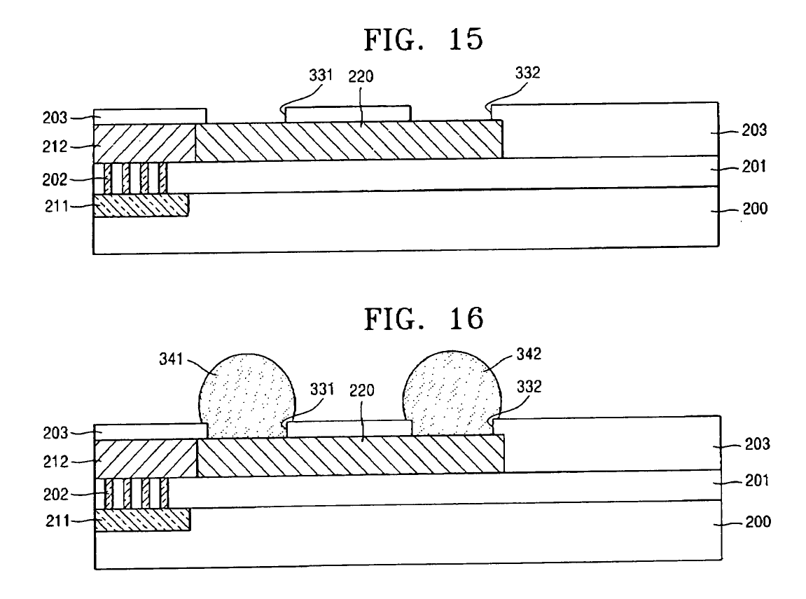

Referring to FIGS. 9 and 15, the passivation layer 203 covers the upper pads 212, the redistribution connecting wires 220 and the insulating layer 201. The first openings 331 and the second openings 332 for exposing the redistribution connecting wires 320 are formed by removing a portion of the passivation layer 203. The first openings 331 receive the test bumps 341. The second openings 332 receive the mounting bumps 342. The first openings 331 are positioned at a predetermined distance (d) from the upper pads 212. The first openings 331 are closer to the upper pads 212 than the second openings 332.

Referring to FIGS. 10 and 16, the test bumps 341 and the mounting bumps 342 are formed using a conventional bump forming method such as, for example, an electrolytic plating process, a screen printing process, a ball placement process. The test bumps 341 are disposed on portions of the upper pads 212 exposed by the first openings 331. The mounting bumps 342 are disposed on portions of the redistribution connecting wires 220 exposed by the second openings 332. The test bumps 341 and the mounting bumps 342 can be formed of gold or solder.

Although exemplary embodiments have been described herein with reference to the accompanying drawings, it is to be understood that the present invention is not limited to such exemplary embodiments, and that various other changes and modifications may be affected therein by one of ordinary skill in the related art without departing from the scope or spirit of the invention. All such changes and modifications are intended to be included within the scope of the invention as defined by the appended claims.

1. A semiconductor package comprising:
a plurality of pads disposed along a surface edge of a semiconductor chip;
a plurality of mounting bumps formed on a surface of the semiconductor chip and disposed away from the plurality of pads at a predetermined distance;
a plurality of redistribution connecting wires for electrically connecting the plurality of pads to the plurality of mounting bumps; and
a plurality of test bumps disposed on the plurality of pads.

2. The semiconductor package of claim 1, wherein the redistribution connecting wires are formed of a conductive layer, each of the redistribution connecting wires having a first end contacting a corresponding pad and a second end contacting a corresponding mounting bump.

3. The semiconductor package of claim 1, wherein each of the plurality of test bumps contacts a portion of an upper surface of a corresponding redistribution connecting wire, the corresponding redistribution connecting wire contacting a corresponding pad.

4. The semiconductor package of claim 1, wherein the plurality of mounting bumps and the plurality of test bumps are formed from a same material by a same process.

5. The semiconductor package of claim 4, wherein the plurality of mounting bumps and the plurality of test bumps are formed of gold or solder.

6. A semiconductor package comprising:
a semiconductor chip;
a plurality of pads disposed along a surface edge of the semiconductor chip;
a plurality of mounting bumps formed on a surface of the semiconductor chip and disposed away from the plurality of pads at a predetermined distance;
a plurality of redistribution connecting wires for electrically connecting the plurality of pads to the plurality of mounting bumps; and
a plurality of test bumps disposed between the plurality of pads and the plurality of mounting bumps.

7. The semiconductor package of claim 6, wherein the plurality of redistribution connecting wires are formed of a conductive layer, and each of the plurality of redistribution connecting wires has a first end contacting a corresponding pad and a second end contacting a corresponding mounting bump.

8. The semiconductor package of claim 6, wherein the plurality of mounting bumps and the plurality of test bumps are formed from a same material by a same process.

9. The semiconductor package of claim 8, wherein the plurality of mounting bumps and the plurality of test bumps are formed of gold or solder.

10. The semiconductor package of claim 6, wherein a size of one of the plurality of test bumps is greater than a size of one of the plurality of pads.

11. The semiconductor package of claim 6, wherein the distance between the plurality of test bumps and the plurality of pads are substantially the same.

12. A method for fabricating a semiconductor package comprising:
forming a first insulating layer on a semiconductor chip, the first insulating layer having openings for exposing a portion of a plurality of pads of the semiconductor chip;
forming a plurality of redistribution connecting wires on the first insulating layer, wherein the plurality of redistribution connecting wires are electrically connected to the plurality of pads;
forming a second insulating layer having openings for exposing a first region and a second region of the plurality of redistribution connecting wires; and forming a plurality of mounting bumps and a plurality of test bumps on the first region and the second region of the plurality of redistribution connecting wires, respectively.

13. The method of claim 12, wherein the first region is formed opposite from the plurality of pads and the second region is formed on the plurality of pads.

14. The method of claim 12, wherein the first region is formed opposite from the plurality of pads and the second region is formed between the plurality of pads and the first region.

15. The method of claim 12, wherein the plurality of mounting bumps and the plurality of test bumps are simultaneously formed in one process.

16. The method of claim 15, wherein the plurality of mounting bumps and the plurality of test pumps are formed of gold or solder.
